(19) United States
(12) Patent Application Publication
(10) Pub. No.: US 2025/0275114 A1
(43) Pub. Date: Aug. 28, 2025

(54) CAPACITOR STRUCTURE AND METHOD OF MANUFACTURING THE SAME

(71) Applicant: NANYA TECHNOLOGY CORPORATION, New Taipei city (TW)

(72) Inventor: Ning-Shuang HSU, New Taipei City (TW)

(21) Appl. No.: 18/588,713

(22) Filed: Feb. 27, 2024

(51) Int. Cl. H10B 12/00

(52) U.S. Cl. CPC H10B 12/033; H10B 12/31

(57) ABSTRACT

A manufacturing method of capacitor structures is provided. A template layer is formed over a substrate. A recess is formed in the template layer. A capacitor lower electrode layer is formed on an inner surface of the recess and a top surface of the template layer. The capacitor lower electrode layer has a base located at a bottom of the recess, a side portion extending upwardly from the base to the top surface of the template layer, and a top portion located on the template layer. A ratio of a thickness of the base to a thickness of a topmost side portion of the capacitor lower electrode layer is in a range between about 70% to about 80%. A capacitor dielectric layer is formed in the recess and on the capacitor lower electrode layer. A capacitor upper electrode layer is formed on the capacitor dielectric layer.

### BACKGROUND

### Field of Invention

The present disclosure relates generally to a method of manufacturing semiconductor devices and, more specifically, to a method of manufacturing a single-side capacitor structure.

### Description of Related Art

Capacitors continue to have increasing aspect ratios in higher generation integrated circuitry fabrication. For example, dynamic random access memory (DRAM) capacitors now have elevations of from 1 to 3 microns, and widths of less than or equal to about 0.1 micron.

A common type of capacitor is a so-called container device. A storage electrode of such device is shaped as a container. Dielectric material and another capacitor electrode may be formed within the container and/or along an outer edge of the container, which can form a capacitor having high capacitance and a small footprint.

Container-shaped storage nodes are becoming increasingly taller and narrower (i.e., are being formed with higher aspect ratios) in an effort to achieve desired levels of capacitance while decreasing the amount of semiconductor real estate consumed by individual capacitors. Unfortunately, high aspect ratio container-shaped storage nodes may decrease the step coverage of the lower electrode of the capacitor.

Accordingly, it is desired to develop new storage node structures, and new methods for forming storage node structures.

### SUMMARY

It is therefore one objective of the present disclosure to provide a novel method of manufacturing a capacitor structure. This method provides a cost effective and efficient solution to the challenges of achieving high quality and high yield fabrication of DRAM devices with single side capacitor. A capacitor structure obtained by this manufacturing method is also provided in the present disclosure.

One object of the present disclosure is to provide a method of manufacturing a capacitor structure. The method includes the following steps. A template layer is formed over a substrate. A recess is formed in the template layer. A capacitor lower electrode layer is formed on an inner surface of the recess and a top surface of the template layer. The capacitor lower electrode layer has a base located at a bottom of the recess, a side portion extending upwardly from the base to the top surface of the template layer, and a top portion located on the top surface of the template layer. A ratio of a thickness of the base to a thickness of a topmost side portion of the capacitor lower electrode layer is in a range between about 70% to about 80%. The top portion of the capacitor lower electrode layer is removed to form a capacitor lower electrode. A capacitor dielectric layer is formed in the recess and on the capacitor lower electrode. A capacitor upper electrode layer is formed in the recess and on the capacitor dielectric layer.

In some embodiments, the capacitor lower electrode layer includes TiSiN.

In some embodiments, the recess has a depth to width aspect ratio of about 36 to about 46.

In some embodiments, forming the capacitor lower electrode layer is performed by an atomic layer deposition process.

In some embodiments, the atomic layer deposition process includes a plurality of cycles, and each cycle includes providing a titanium-containing reactant gas; providing a first purging gas; providing a nitrogen-containing reactant gas; providing a second purging gas; providing a silicon-containing reactant gas; and providing a third purging gas.

In some embodiments, the titanium-containing is TiCl₄, the nitrogen-containing reactant gas is NH₃, the silicon-containing reactant gas is SiCl₂H₂, and the first purging gas, the second purging gas, and the third purging gas are an inert gas.

In some embodiments, the inert gas is N₂.

In some embodiments, the flow rate of the first purging gas is in a range from about 4000 sccm to about 7000 sccm.

In some embodiments, the flow rate of the second purging gas is in a range from about 4000 sccm to about 7000 sccm.

In some embodiments, the flow rate of the titanium-containing reactant gas is in a range from about 50 sccm to about 200 sccm.

In some embodiments, the flow rate of the third purging gas is in a range from about 4000 sccm to about 7000 sccm.

In some embodiments, the flow rate of the silicon-containing reactant gas is in a range from about 20 sccm to about 60 sccm.

Another object of the present disclosure is to provide a capacitor structure. The capacitor structure includes a substrate, a template layer, a capacitor lower electrode, a capacitor dielectric layer, and a capacitor upper electrode layer. The template layer is disposed over the isolation layer. The template layer has a recess penetrating the template layer. The capacitor lower electrode is disposed on an inner surface of the recess and surrounded by the template layer. The capacitor lower electrode has a base and a side portion extending upwardly from the base to a top surface of the template layer. A ratio of a thickness of the base to a thickness of a topmost side portion of the capacitor lower electrode is in a range between about 70% and about 80%. The capacitor dielectric layer is disposed in the recess and on the capacitor lower electrode. The capacitor upper electrode layer is disposed in the recess and on the capacitor dielectric layer.

In some embodiments, a top surface of the capacitor lower electrode is substantially coplanar with the top surface of the template layer.

In some embodiments, the capacitor structure further includes a conductive layer under the capacitor lower electrode.

In some embodiments, the base of the capacitor lower electrode is substantially aligned with the conductive layer.

In some embodiments, the capacitor structure further includes an implant region under the capacitor lower electrode and the conductive layer.

In some embodiments, the base of the capacitor lower electrode is substantially aligned with the implant region.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view schematically depicting a process flow for manufacturing a single side capacitor structure in accordance with one embodiment of present disclosure.

FIG. 2 is a cross-sectional view schematically depicting a process flow for manufacturing a single side capacitor structure in accordance with one embodiment of present disclosure.

FIG. 3 is a schematic view schematically depicting a capacitor lower electrode layer formed in a recess by a parameter-adjusted atomic layer deposition process in accordance with one embodiment of present disclosure.

FIG. 4 is a cross-sectional view schematically depicting a capacitor lower electrode layer formed in a recess without a parameter-adjusted atomic layer deposition process in accordance with one comparative example.

FIG. 5 is a cross-sectional view schematically depicting a process flow for manufacturing a single side capacitor structure in accordance with one embodiment of present disclosure.

FIG. 6 is a cross-sectional view schematically depicting a process flow for manufacturing a single side capacitor structure in accordance with one embodiment of present disclosure.

FIG. 7 is a cross-sectional view schematically depicting a process flow for manufacturing a single side capacitor structure in accordance with one embodiment of present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

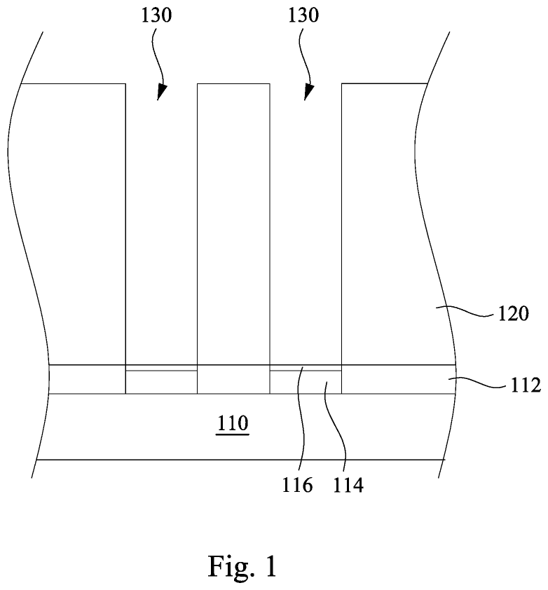

FIG. 1 is a cross-sectional view schematically depicting a process flow for manufacturing a single side capacitor structure in accordance with one embodiment of present disclosure. First, as shown in FIG. 1, a substrate 110 is provided to serve as a base for forming devices, components, or circuits. In some embodiments, the substrate 110 may be a semiconductor substrate. The substrate 110 may include, consist essentially of, or consist of monocrystalline silicon, and may be referred to as a semiconductor substrate, or as a portion of a semiconductor substrate. The terms “semiconductive substrate,” “semiconductor construction” and “semiconductor substrate” mean any construction including semiconductive material, including, but not limited to, bulk semiconductive materials such as a semiconductive wafer (either alone or in assemblies comprising other materials), and semiconductive material regions (either alone or in assemblies comprising other materials). The term “substrate” refers to any supporting structure, including, but not limited to, the semiconductive substrates described above. Although the substrate 110 in this embodiment is shown to be homogenous, the substrate may include numerous materials in some embodiments. For instance, the substrate 110 may correspond to a semiconductor substrate containing one or more materials associated with integrated circuit fabrication. In such embodiments, such materials may correspond to one or more of refractory metal materials, barrier materials, diffusion materials, insulator materials, etc.

Referring again to FIG. 1, an isolation layer 112 is formed over the substrate 110 with source/drain implant regions 114 are shown to be between the isolation layer 112. The isolation layer 112 may correspond to shallow trench isolation regions in the substrate 110, and may be filled with any suitable electrically insulated composition or combination of electrically insulated compositions. For instance, in some embodiments the isolation layers 112 may be filled with one or more of silicon dioxide, silicon nitride and silicon oxynitride. The source/drain implant region 114 may include any suitable dopant or combination of dopants and in some embodiments may correspond to an n-type doped region of semiconductor material of substrate 110. For instance, the substrate 110 may include monocrystalline silicon, and source/drain implant region 114 may correspond to a region of the substrate 110 that is conductively doped with one or both of phosphorus and arsenic. Alternatively, the source/drain implant region 114 may be formed of metal such as tungsten (W) or layers such as TiN/W. The source/drain implant region 114 is one example of an electrical node that may be electrically connected with the base of a storage node. Detailed description will be provided in the following embodiment.

A template layer 120 is formed over the substrate 110 and covers the isolation layer 112 and the implant region 114. In some embodiments, the template layer 120 may be a sacrificial layer made of any suitable composition or combination of compositions; and in some embodiments may comprise one or more of silicate glass (for instance, borophosphosilicate glass, phosphosilicate glass, fluorosilicate glass, etc.), spin-on-dielectric, and silicon dioxide formed from tetraethyl orthosilicate (TEOS), or may be a semiconductive layer such as amorphous silicon or polysilicon. Please note that in this embodiment, only one template layer 120 is provided on the substrate 110. In other embodiment, there may be two or more stacked template layer 120 disposed on the substrate 110.

Refer again to FIG. 1, a plurality of recesses 130 are formed in the template layer 120 for accommodating a capacitor lower electrode layer to be manufactured. The recess 130 extends through the entire thickness of the template layer 120 and exposes the source/drain implant region 114 thereunder. In some embodiments, each recess 130 has a depth to width aspect ratio of about 36 to about 46, such as 37, 38, 39, 40, 41, 42, 43, 44, or 45. In the shown embodiment, the source/drain implant region 114 is configured to be electrically connected with the capacitor lower electrode layer. Thus, a conductive layer 116 is required to be pre-formed over the source/drain implant region 114 to improve electrical coupling between the base of the capacitor lower electrode layer and the conductively-doped implant region 114. For instance, the conductive layer 116 may be a metal silicide (e.g., titanium silicide, tungsten silicide, etc.) layer formed by silicide process. Alternatively, if the source/drain implant region 114 is formed of metal (ex. W) or metal layers (ex. TiN/W), the conductive layer 116 may be omitted.

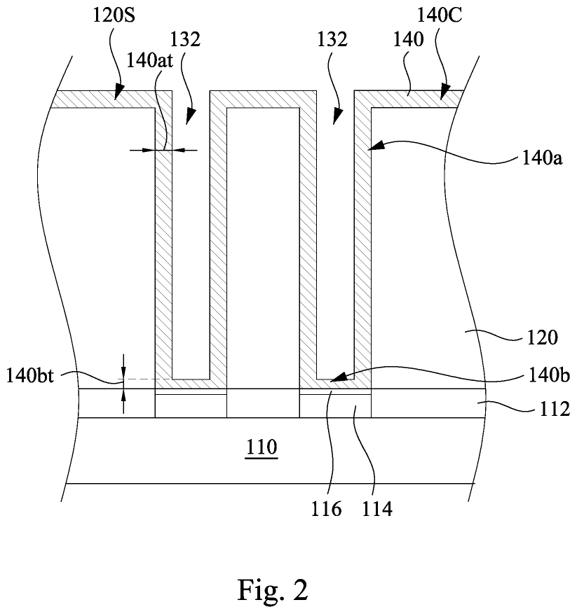

FIG. 2 is a cross-sectional view schematically depicting a process flow for manufacturing a single side capacitor structure in accordance with one embodiment of present disclosure. After providing the template layer 120 and the recesses 130, a capacitor lower electrode layer 140 is formed an inner surface of the recesses 130 and a top surface 120S of the template layer 120. The capacitor lower electrode layer 140 does not fill the recesses 130, therefore, the smaller recesses 132 are defined in each former recess 130. In this embodiment, the capacitor lower electrode layer 140 will be used to form the storage node structure with variable thickness. The capacitor lower electrode layer 140 has a base 140b located at a bottom of the recesses 130, a side portion 140a extending upwardly from the base 140b to the top surface 120S of the template layer 120, and a top portion 140C disposed on the top surface 120S of the template layer 120. To be specific, a ratio (namely step coverage) of a thickness 140bt of the base 140b to a thickness 140at of a topmost side portion of the capacitor lower electrode layer 140 is in a range between about 70% to about 80%, such as about 72%, about 74%, about 76%, or about 78%. In some embodiments, the capacitor lower electrode layer 140 includes TiSiN. In one embodiment, the capacitor lower electrode layer 140 consists of TiSiN. In this embodiment, the capacitor lower electrode layer 120 is performed by an atomic layer deposition (ALD) process.

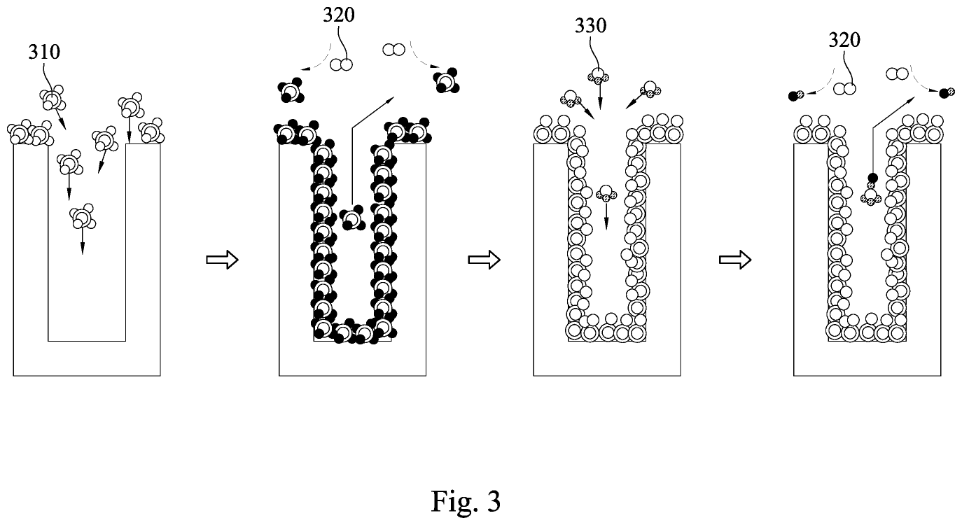

FIG. 3 is a schematic view schematically depicting a capacitor lower electrode layer formed in a recess by a parameter-adjusted atomic layer deposition process in accordance with one embodiment of present disclosure. In this embodiment, the capacitor lower electrode layer 140 is a TiSiN layer formed using ALD. The reactants may include TiCl₄ 310, NH₃ 330, and SiCl₂H₂ (dichlorosilane, DCS) (not shown). The corresponding ALD process includes a plurality of cycles, each cycle including providing a titanium-containing reactant gas, providing a first purging gas, providing a nitrogen-containing reactant gas, providing a second purging gas, providing a silicon-containing reactant gas, providing a third purging gas, and providing a nitrogen-containing reactant gas. In this embodiment, the titanium-containing is TiCl₄, the nitrogen-containing reactant gas is NH₃, the silicon-containing reactant gas is SiCl₂H₂, and the first purging gas, the second purging gas, and the third purging gas are an inert gas. For example, the inert gas may be N₂.

For example, in each cycle, TiCl₄ may be conducted for about 20 seconds to about 50 seconds, with the flow rate in the range between about 50 sccm and about 200 sccm. According to various embodiments, when the flow rate of TiCl₄ is greater than a certain value such as 200 sccm, it will lead to cost going up. To the contrary, when the flow rate of TiCl₄ is less than a certain value such as 50 sccm, it will cause high aspect ratio capacitor structure having such a thin base thickness during the formation of the capacitor lower electrode layer that the structure will become weak and subject to toppling, twisting and/or breaking from an underlying base. Therefore, the flow rate of TiCl₄ may be such as 60 sccm, 70 sccm, 80 sccm, 90 sccm, 100 sccm, 120 sccm, 140 sccm, 160 sccm, or 180 sccm. NH₃ may be conducted for about 20 seconds to about 50 seconds, with the flow rate in the range between about 4000 sccm and about 7000 sccm. According to various embodiments, when the flow rate of NH₃ is greater than a certain value such as 7000 sccm, it may lead to the pump of the equipment to be unable to withstand too high pressure. To the contrary, when the flow rate of NH₃ is less than a certain value such as 4000 sccm, it will cause high aspect ratio capacitor structure having such a thin base thickness during the formation of the capacitor lower electrode layer that the structure will become weak and subject to toppling, twisting and/or breaking from an underlying base. Therefore, the flow rate of NH₃ may be such as 4500 sccm, 5000 sccm, 5500 sccm, 6000 sccm, or 6500 sccm. N₂ is purging for about 20 seconds to about 50 seconds, with the flow rate in the range between about 4000 sccm and about 7000 sccm. According to various embodiments, when the flow rate of N₂ is greater than a certain value such as 7000 sccm, it will lead to cost going up. To the contrary, when the flow rate of N₂ is less than a certain value such as 4000 sccm, it will cause higher pressure issues in the equipment's chambers. Therefore, the flow rate of N₂ may be such as 4500 sccm, 5000 sccm, 5500 sccm, 6000 sccm, or 6500 sccm. The operating conditions of SiCl₄H₂ remain the same as the original.

The reaction chamber may be maintained a pressure of about 3 Torr to about 6 Torr, such as about 3.2 Torr, about 3.4 Torr, about 3.6 Torr, about 3.8 Torr, about 4.0 Torr, about 4.2 Torr, about 4.4 Torr, about 4.6 Torr, or about 4.8 Torr. The reaction chamber may also be maintained at an elevated temperature of about 500° C. to about 600° C., such as about 510° C., about 520° C., about 530° C., about 540° C., about 550° C., about 560° C., about 570° C., about 580° C., or about 195° C.

It should be noted that the flow rate of TiCl₄ and/or NH₃ may be adjusted by increasing 2 times of the original flow rate of TiCl₄ and/or NH₃. When the flow rate of TiCl₄ and/or NH₃ are increased in the deposition chamber, the reactant gases (such as TiCl₄ and NH₃) may allow reaching the bottom of the recess 130 more easily, thereby increasing the thickness of the deposition thin film. In addition, the flow rate of the purge gas 320 may be adjusted by increasing 1.5 times of the original flow rate of the purge gas 320 (such as N₂). When the flow rate of N₂ is increased in the deposition chamber, the purge gas 320 may help remove excess reactant gas and by-products, thereby improving the quality of the deposition thin film. The deposited capacitor lower electrode layer 140 (TiSiN layer) is shown as FIG. 2. The thickness 140at of the topmost side portion 140a of the capacitor lower electrode layer 140 is in the range between about 14.40 μm to about 14.55 μm, such as 14.41 μm, 14.43 un, 14.45 μm, 14.47 μm, 14.49 μm, 15.51 μm, or 15.53 μm. The thickness 140bt of the base 140b of the capacitor lower electrode layer 140 is in the range between about 10.75 μm to about 11.15 μm, such as 10.77 μm, 10.79 un, 10.80 μm, 10.85 μm, 10.90 μm, 10.95 μm, 11.00 μm, 11.05 μm, or 11.10 μm. It may be understood that a ratio (namely step coverage) of the thickness of the base to the thickness of the topmost side portion is in a range between about 70% and about 80%, such as 71%, 72%, 73%, 74%, 75%, 76%, 77%, 78%, or 79%.

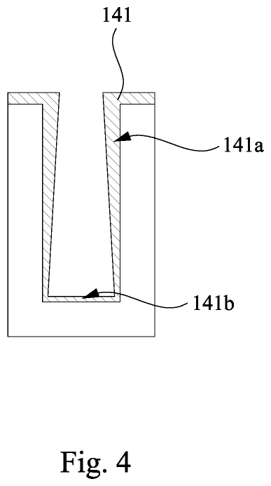

FIG. 4 is a cross-sectional view schematically depicting a capacitor lower electrode layer formed in a recess without a parameter-adjusted atomic layer deposition process in accordance with one comparative example. In this comparative example, in each cycle, TiCl₄ may be conducted for about 20 seconds to about 50 seconds, with the flow rate in the range between about 2000 sccm and about 4000 sccm. NH₃ may be conducted for about 20 seconds to about 50 seconds, with the flow rate in the range between about 2000 sccm and about 4000 sccm. N₂ is purging for about 20 seconds to about 50 seconds, with the flow rate in the range between about 2000 sccm and about 4000 sccm. SiCl₂H₂ may be conducted for about 20 seconds to about 50 seconds, with the flow rate in the range between about 20 sccm and about 60 sccm. The deposited capacitor lower electrode layer 141 (TiSiN layer) is shown as FIG. 4. The thickness of the upper sidewall 141a of the capacitor lower electrode layer 141 is in the range between about 5 nm to about 15 nm. The thickness of the base 141b of the capacitor lower electrode layer 141 is in the range between about 5 nm to about 15 nm. The step coverage shown in FIG. 4 is in a range between about 53% and about 54%. Because the recess 130 has a high depth to width aspect ratio, it is difficult for the reactant gas to reach the bottom of the recess for deposition, so that the profile of the capacitor lower electrode layer 140 appears as shown in FIG. 4. This situation may also lead to high aspect ratio capacitor structure having such a thin base thickness during the formation of the capacitor lower electrode layer that the structure will become weak and subject to toppling, twisting and/or breaking from an underlying base.

Comparing with the comparative example, increasing the flow rate of TiCl₄, NH₃, and/or N₂ in the present disclosure may improve the step coverage while maintain a high productivity.

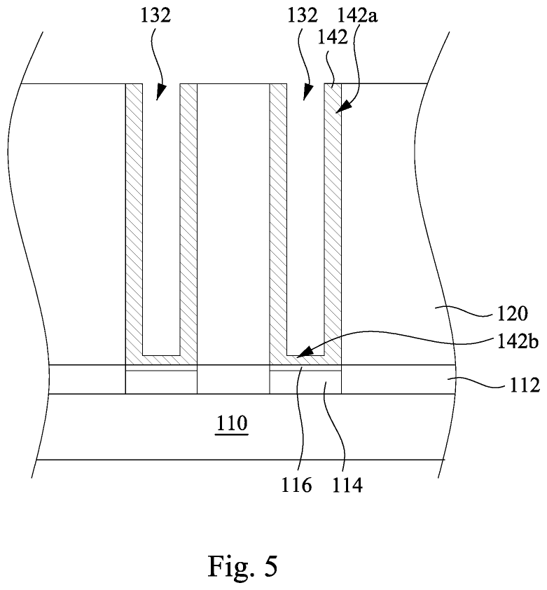

FIG. 5 is a cross-sectional view schematically depicting a process flow for manufacturing a single side capacitor structure in accordance with one embodiment of present disclosure. After forming the capacitor lower electrode layer 140, a chemical mechanical polishing (CMP) process is performed to remove the top portion 140C of the capacitor lower electrode layer 140 on the template layer 120 to form a capacitor lower electrode 142 embedded in the template layer 120. The capacitor lower electrode 142 includes a base 142b along the bottom which is electrically connected with the source/drain implant region 114 (through the conductive layer 116) thereunder, and two side portions 142a extending upwardly from the base 142b. The top surface of the capacitor lower electrode 142 is coplanar with the top surface of the template layer 120. Although there appear to be two separate side portions 142a along the cross-section of the view of FIG. 5, such side portions 142a may be a part of a single sidewall structure when considered in three dimensions, such as a single circular cylinder when viewed from above.

The side portions 142a in the cross-sectional view of FIG. 5 have a substantially constant thickness from the base of the sidewalls to the tops of the sidewalls. The term “substantially constant thickness” means that the thickness is uniform to within tolerances imposed by the fabrication process utilized to form the capacitor lower electrode 142. In some embodiments, the thickness of the side portion 142a of the capacitor lower electrode 142 may be within a range of from about 40 Å to about 100 Å, and may be, for example, about 50 Å, 60 Å, 70 Å, 80 Å, or 90 Å. In some embodiments, the thickness may vary from the top of the sidewalls to the base of the sidewalls, with the upper portion of the sidewall being thicker than the lower portion of the sidewall due to difficulties associated with the uniform deposition of the capacitor lower electrode layer 140 within a high aspect ratio opening during formation of the capacitor lower electrode 142.

In the shown embodiment, the source/drain implant region 114 is electrically connected to the capacitor lower electrode 142. In some embodiments, the capacitor lower electrode 142 is ultimately incorporated into a capacitor, and such capacitor is ultimately connected to a transistor to form a DRAM unit cell. Thus, the source/drain implant region 114 may connect to a transistor gate that gatedly couples the source/drain implant region 114 to another source/drain implant region (not shown). The transistor gate may be part of an access line (i.e., a word line), and the other source/drain region may be connected to a bit line. Accordingly, the capacitor lower electrode 142 may be uniquely addressed through the combination of the bit line and the access line. The shown capacitor lower electrode 142 may be one of a large plurality of storage node structures that are subjected to identical processing during fabrication of a DRAM array.

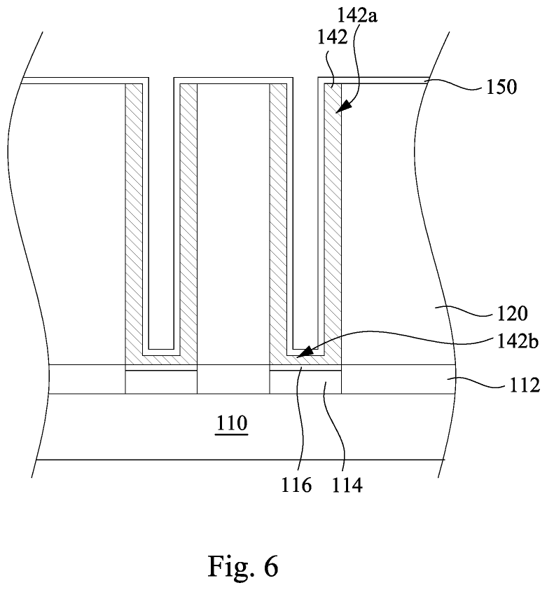

FIG. 6 is a cross-sectional view schematically depicting a process flow for manufacturing a single side capacitor structure in accordance with one embodiment of present disclosure. As shown in FIG. 6, after the capacitor lower electrode 142 is planarized, a capacitor dielectric layer 150 is formed in the recess 132 and on the capacitor lower electrode 142. The capacitor dielectric layer 150 is formed conformally along the inner surfaces of the capacitor lower electrode 142 including the side portions 142a and the base 142b and the top surface of the template layer 120. In some embodiments, the capacitor dielectric layer 150 may include any suitable composition or combination of compositions, such as one or both of silicon nitride and silicon dioxide. The capacitor dielectric layer 150 may be formed utilizing any suitable methods, including, for example, one or more of atomic layer deposition (ALD), chemical vapor deposition (CVD), and physical vapor deposition (PVD).

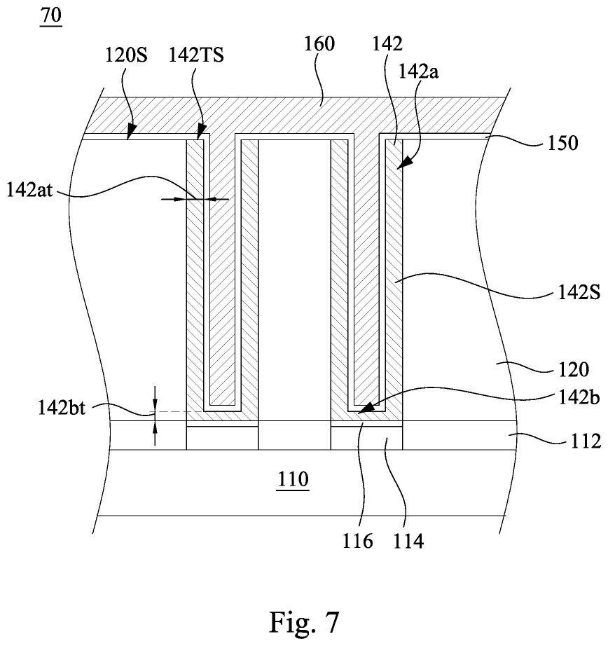

FIG. 7 is a cross-sectional view schematically depicting a process flow for manufacturing a single side capacitor structure in accordance with one embodiment of present disclosure. A capacitor upper electrode layer 160 is then formed in the recess and on the capacitor dielectric layer 150. The capacitor upper electrode layer 160 fills up the recess formed in the side portions 142a and the base 142b of the capacitor lower electrode 142 and covers the entire surface of the template layer 120. In some embodiments, the capacitor upper electrode layer 160 may include any suitable composition or combination of compositions, such as one or more of various metals (for instance, titanium, tungsten, etc.), metal-containing compositions (for instance, metal nitride, metal silicide, etc.) and conductively-doped semiconductor materials (for instance, conductively-doped silicon, conductively-doped germanium, etc.). The capacitor upper electrode layer 160 may be formed utilizing any suitable methods, including, for example, one or more of atomic layer deposition (ALD), chemical vapor deposition (CVD), and physical vapor deposition (PVD).

The capacitor structure 70 shown in FIG. 7 includes a substrate 110, a template layer 120, a capacitor lower electrode 142, a capacitor dielectric layer 150, and a capacitor upper electrode layer 160. The template layer 120 is disposed over the substrate 110, in which the template layer 120 has a recess 130 penetrating the template layer 120. In some embodiments, the capacitor structure 70 further includes an isolation layer 112 disposed between the substrate 110 and the template layer 120. The various features of each element (the substrate 110, the isolation layer 112, and the template layer 120) as shown in FIG. 7 have been described hereinbefore, and the details are not repeated herein.

The capacitor lower electrode 142 is disposed on an inner surface of the recess 130 and surrounded by the template layer 120. The capacitor lower electrode 142 has a base 142b and a side portion 142a extending upwardly from the base 142b to a top surface 120S of the template layer 120. A ratio (namely step coverage) of a thickness 142bt of the base 142b to a thickness 142at of a topmost side portion 142a of the capacitor lower electrode 142 is in a range between about 70% and about 80%, such as 71%, 72%, 73%, 74%, 75%, 76%, 77%, 78%, or 79%. In some embodiments, a top surface 142TS of the capacitor lower electrode 142 is coplanar with the top surface 120S of the template layer 120. The capacitor dielectric layer 150 is disposed in the recess 130 and on the capacitor lower electrode 142. The capacitor upper electrode layer 160 is disposed in the recess 130 and on the capacitor dielectric layer 150.

The capacitor structure 70 may further include a conductive layer 116 under the capacitor lower electrode 142. In some embodiments, the base 142b of the capacitor lower electrode 142 is substantially aligned with the conductive layer 116. The term “substantially aligned” used herein refers to a vertical projection of the conductive layer 116 overlapped with a vertical projection of the base 142b of the capacitor lower electrode 142. In addition, the capacitor structure 70 may further include an implant region 114 under the capacitor lower electrode 142 and the conductive layer 116. In some embodiments, the base 142b of the capacitor lower electrode 142 is substantially aligned with the implant region 114.

The embodiment of FIG. 7 shows the capacitor lower electrode 142 incorporated into a capacitor including such storage node in combination with the capacitor dielectric layer 150 and the capacitor upper electrode layer 160. This single side capacitor may be utilized in combination with a transistor (which may correspond to the circuit in the substrate 110) to form a DRAM unit cell, and such unit cell may be representative of a large number of unit cells simultaneously formed and incorporated into a DRAM array.

By increasing the reactant gas flow rate of TiCl₄ and/or NH₃, the gas pressure in the deposition chamber is enhanced, thereby allowing the reactant gas reaching the bottom of the recess having a high aspect ratio. In addition, increasing the purge gas flow rate of N₂ helps remove excess reactant gas and by-products, thereby improving the quality of the deposition thin film. The method of manufacturing the capacitor structure of the present disclosure provides a cost-effective and efficient solution to the changes of achieving high quality and high yield fabrication of DRAM devices with single side capacitor structures.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a capacitor structure, comprising:
forming a template layer over a substrate;
forming a recess in the template layer;
forming a capacitor lower electrode layer on an inner surface of the recess and a top surface of the template layer, wherein the capacitor lower electrode layer has a base located at a bottom of the recess, a side portion extending upwardly from the base to the top surface of the template layer, and a top portion located on the top surface of the template layer, wherein a ratio of a thickness of the base to a thickness of a topmost side portion of the capacitor lower electrode layer is in a range between about 70% to about 80%;
removing the top portion of the capacitor lower electrode layer to form a capacitor lower electrode;
forming a capacitor dielectric layer in the recess and on the capacitor lower electrode; and
forming a capacitor upper electrode layer in the recess and on the capacitor dielectric layer.

2. The method of claim 1, wherein the recess has a depth to width aspect ratio of about 36 to about 46.

3. The method of claim 1, wherein the capacitor lower electrode layer comprises TiSiN.

4. The method of claim 1, wherein forming the capacitor lower electrode layer is performed by an atomic layer deposition process.

5. The method of claim 4, wherein the atomic layer deposition process comprises a plurality of cycles, and each cycle comprises:
providing a titanium-containing reactant gas;
providing a first purging gas;
providing a nitrogen-containing reactant gas;
providing a second purging gas;
providing a silicon-containing reactant gas; and
providing a third purging gas.

6. The method of claim 5, wherein the titanium-containing is TiCl₄, the nitrogen-containing reactant gas is NH₃, the silicon-containing reactant gas is SiCl₂H₂, and the first purging gas, the second purging gas, and the third purging gas are an inert gas.

7. The method of claim 6, wherein the inert gas is N₂.

8. The method of claim 5, wherein a flow rate of the first purging gas is in a range from about 4000 sccm to about 7000 sccm.

9. The method of claim 5, wherein a flow rate of the second purging gas is in a range from about 4000 sccm to about 7000 sccm.

10. The method of claim 5, wherein a flow rate of the titanium-containing reactant gas is in a range from about 50 sccm to about 200 sccm.

11. The method of claim 5, wherein a flow rate of the third purging gas is in a range from about 4000 sccm to about 7000 sccm.

12. The method of claim 5, wherein a flow rate of the silicon-containing reactant gas is in a range from about 20 sccm to about 60 sccm.

13. A capacitor structure, comprising:
a substrate;
a template layer disposed over the substrate, wherein the template layer has a recess penetrating the template layer;
a capacitor lower electrode disposed on an inner surface of the recess and surrounded by the template layer, the capacitor lower electrode has a base and a side portion extending upwardly from the base to a top surface of the template layer, wherein a ratio of a thickness of the base to a thickness of a topmost side portion of the capacitor lower electrode is in a range between about 70% and about 80%;
a capacitor dielectric layer disposed in the recess and on the capacitor lower electrode; and
a capacitor upper electrode layer disposed in the recess and on the capacitor dielectric layer.

14. The capacitor structure of claim 13, wherein a top surface of the capacitor lower electrode is substantially coplanar with the top surface of the template layer.

15. The capacitor structure of claim 13, further comprising a conductive layer under the capacitor lower electrode.

16. The capacitor structure of claim 15, wherein the base of the capacitor lower electrode is substantially aligned with the conductive layer.

17. The capacitor structure of claim 15, further comprising an implant region under the capacitor lower electrode and the conductive layer.

18. The capacitor structure of claim 17, wherein the base of the capacitor lower electrode is substantially aligned with the implant region.
